(19) United States
(12) Patent Application Publication
(10) Pub. No.: US 2026/0247873 A1
(43) Pub. Date: Aug. 20, 2026

(54) Chains of semiconductor quantum dots coupled via superconductors

(71) Applicant: Technische Universiteit Delft, Delft (NL)

(72) Inventors: Srijit Goswami, Delft (NL); Christian Kraglund Dersen, Delft (NL)

(73) Assignee: Technische Universiteit Delft, Delft (NL)

(21) Appl. No.: 19/489,611

(22) PCT Filed: May 8, 2024
(86) PCT No.: PCT/EP2024/062726

§ 371 Date: Dec. 3, 2025

(30) Foreign Application Priority Data
Jun. 9, 2023 (NL) 20350587

(51) Int. Cl. H10N 69/00; H10N 60/10; H10N 60/12; H10N 60/82

(52) U.S. Cl. CPC H10N 69/00; H10N 60/12; H10N 60/128; H10N 60/82

(57) ABSTRACT

The invention relates to a semiconductor-superconductor hybrid structure and an integrated quantum dot structure for controllably coupling quantum dots, and further relates to an integrated quantum circuit architecture for realizing a protected qubit. The semiconductor-superconductor hybrid structure comprises a semiconductor extending in a first direction and hosting a first quantum dot and a second quantum dot; a superconductor extending in a second direction substantially perpendicular to the first direction, the superconductor being partly formed on top of a region of the semiconductor that is located in between the first and second quantum dots with respect to the first direction; and a control gate configured to control a coupling between the first and second quantum dots, the coupling being mediated by one or more electrons and involving the superconductor.

### FIELD OF THE INVENTION

The invention relates to a semiconductor-superconductor hybrid structure and an integrated quantum dot structure for controllably coupling quantum dots, and further relates to an integrated quantum circuit architecture for realizing a protected qubit.

### BACKGROUND ART

Quantum computing requires a quantum-mechanical system with at least two quantum states that can be manipulated in a controlled manner so as to serve as a computational basis, a qubit. Various candidates for physically realizing such a suitable quantum-mechanical system are continuously being researched, including naturally occurring systems such as atoms as well as human-built systems such as manufactured quantum circuits.

Despite numerous efforts in building and controlling human-built systems for quantum computing, state-of-the-art hardware for implementing quantum computing is still limited by noise sources depending on the specific implementation. Such noise sources cause errors in operations and can prevent the hardware from performing useful computations that are not already feasible on a classical computer.

There is a need for circuit architectures that enable efficient control of components involved in the architecture. Furthermore, there is need for circuit architectures that are capable of realizing a qubit that is more robust against noise sources.

### SUMMARY OF THE INVENTION

Therefore, a semiconductor-superconductor hybrid structure, an integrated quantum dot structure, and an integrated quantum circuit architecture are provided.

The semiconductor-superconductor hybrid structure comprises: a semiconductor extending in a first direction and hosting a first quantum dot and a second quantum dot; a superconductor extending in a second direction substantially perpendicular to the first direction, the superconductor being partly formed on top of a region of the semiconductor that is located in between the first and second quantum dots with respect to the first direction; and a control gate configured to control a coupling between the first and second quantum dots, the coupling being mediated by one or more electrons and involving the superconductor, wherein the semiconductor is implemented as a two-dimensional electron gas, 2DEG, or a two-dimensional hole gas, 2DHG.

The semiconductor-superconductor hybrid structure can exhibit highly controllable dot-dot interactions between the respective involved quantum dots.

Preferably, the coupling comprises: elastic co-tunnelling, ECT, related to single-electron tunnelling between the first and second quantum dots with a tunnel coupling amplitude; and crossed Andreev reflection, CAR, related to Cooper-pair splitting with a superconducting coupling amplitude, the Cooper-pair splitting involving a Cooper-pair of electrons that is formed in a region of the superconductor that is located in proximity to the region of the semiconductor.

Preferably, the control gate is configured to control the coupling so as to tune a relative strength between the tunnel coupling amplitude and the superconducting coupling amplitude to be equal.

Preferably, the semiconductor further comprises one or more further quantum dots so as to host a chain of quantum dots, wherein in between each two neighbouring quantum dots, a respective part of the superconductor protrudes on a respective region of the semiconductor, the respective region being located in between the respective two neighbouring quantum dots.

The integrated quantum dot structure comprises: a semiconductor extending in a first direction and hosting a first quantum dot, a second quantum dot, a third quantum dot and a fourth quantum dot; a first superconductor extending in a second direction substantially perpendicular to the first direction, the first superconductor being partly formed on top of a first region of the semiconductor, the first region being located in between the first and second quantum dots with respect to the first direction; a first control gate configured to control a first coupling between the first and second quantum dots, the first coupling being mediated by one or more electrons and involving the first superconductor; a second superconductor extending in the second direction, the second superconductor being partly formed on top of a second region of the semiconductor, the second region being located in between the third and fourth quantum dots with respect to the first direction; a second control gate configured to control a second coupling between the third and fourth quantum dots, the second coupling being mediated by one or more electrons and involving the second superconductor; and an electrostatic control gate configured to control a tunnel coupling amplitude of single-electron tunnelling between the second quantum dot and the third quantum dot.

The integrated quantum dot structure, involving the specific arrangement of the quantum dots and the first and second control gates and the electrostatic control gate, allows stable operation of electron transitions in between the involved quantum dots and for precise gate control of involved Majorana bound states, MBSs, and couplings between them.

Preferably, each of the first and second coupling comprises elastic co-tunnelling, ECT, coupling related to single-electron tunnelling between the respective first and second quantum dots or third and fourth quantum dots, with a respective tunnel coupling amplitude, and each of the first and second coupling comprises crossed Andreev reflection, CAR, coupling related to Cooper-pair splitting with a respective superconducting coupling amplitude between the respective first and second quantum dots or third and fourth quantum dots, the Cooper-pair splitting involving a Cooper-pair of electrons that is formed in a respective region of the respective superconductor that is located in proximity to the respective region of the semiconductor.

The integrated quantum circuit architecture comprises the integrated quantum dot structure, a Josephson junction, and a capacitor element; wherein the first superconductor and the second superconductor are connected to each other so as to form the Josephson junction, wherein the Josephson junction is configured to exhibit a Josephson energy, wherein the capacitor element is configured to provide a capacitive coupling, wherein a loop is formed by the first superconductor, the Josephson junction, the second superconductor, and the quantum dots.

The integrated quantum circuit architecture can achieve separate controllability that allows for full control of associated non-linear potentials/energy couplings and thereby can achieve desired controllability of two quantum states forming a qubit.

Preferably, the Josephson junction involving the first and second superconductors forms a Superconductor-NormalMetal-Superconductor, SNS, Josephson junction.

Preferably, the first control gate is further configured to tune a relative strength between the first tunnel coupling amplitude and the first superconducting coupling amplitude to be equal; and the second control gate is further configured to tune a relative strength between the second tunnel coupling amplitude and the second superconducting coupling amplitude to be equal.

Preferably, the integrated quantum circuit architecture further comprises a control gate configured to control the Josephson energy of the Josephson junction.

Preferably, the semiconductor is implemented as a two-dimensional electron gas, 2DEG, or a two-dimensional hole gas, 2DHG.

Preferably, the superconductor has a width in between 5 nm and 250 nm.

Preferably, the semiconductor has a width in between 5 nm and 500 nm.

Preferably, the semiconductor is based on one or more of Indium arsenide, InAs, or Indium antimonide, InSb, or Gallium arsenide, GaAs, or Germanium, Ge, or Indium arsenide antimonide, InAsSb, and the superconductor is based on one or more of Aluminium, Al, or Niobium, Nb, or Niobium Titanium Nitride, NbTiN.

Preferably, the semiconductor is based on Indium arsenide, InAs, and the superconductor is based on Aluminium, Al, or the semiconductor is based on Indium antimonide, InSb, and the superconductor is based on Al, or the semiconductor is based on Indium arsenide antimonide, InAsSb, and the superconductor is based on Al.

### BRIEF DESCRIPTION OF THE DRAWINGS

Embodiments of the present disclosure will be described herein below with reference to the accompanying drawings. However, the embodiments of the present disclosure are not limited to the specific embodiments and should be construed as including all modifications, changes, equivalent devices and methods, and/or alternative embodiments of the present disclosure.

The terms “have,” “may have,” “include,” and “may include” as used herein indicate the presence of corresponding features (for example, elements such as numerical values, functions, operations, or parts), and do not preclude the presence of additional features.

The terms “A or B,” “at least one of A or/and B,” or “one or more of A or/and B” as used herein include all possible combinations of items enumerated with them. For example, “A or B,” “at least one of A and B,” or “at least one of A or B” means (1) including at least one A, (2) including at least one B, or (3) including both at least one A and at least one B.

The terms such as “first” and “second” as used herein may modify various elements regardless of an order and/or importance of the corresponding elements, and do not limit the corresponding elements. These terms may be used for the purpose of distinguishing one element from another element. For example, a first element may be referred to as a second element without departing from the scope the present invention, and similarly, a second element may be referred to as a first element.

It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. To the contrary, it will be understood that, when an element (for example, a first element) is “directly coupled with/to” or “directly connected to” another element (for example, a second element), there is no intervening element (for example, a third element) between the element and another element.

The expression “configured to (or set to)” as used herein may be used interchangeably with “suitable for” “having the capacity to” “designed to” “adapted to” “made to,” or “capable of” according to a context. The term “configured to (set to)” does not necessarily mean “specifically designed to” in a hardware level. Instead, the expression “apparatus configured to . . . ” may mean that the apparatus is “capable of . . . ” along with other devices or parts in a certain context.

The terms used in describing the various embodiments of the present disclosure are for the purpose of describing particular embodiments and are not intended to limit the present disclosure. As used herein, the singular forms are intended to include the plural forms as well, unless the context clearly indicates otherwise. All of the terms used herein including technical or scientific terms have the same meanings as those generally understood by an ordinary skilled person in the related art unless they are defined otherwise. The terms defined in a generally used dictionary should be interpreted as having the same or similar meanings as the contextual meanings of the relevant technology and should not be interpreted as having ideal or exaggerated meanings unless they are clearly defined herein. According to circumstances, even the terms defined in this disclosure should not be interpreted as excluding the embodiments of the present disclosure.

The person skilled in the art will understand that the features described above and/or below may be combined in any way deemed useful. The drawings of the present disclosure show examples/embodiments of the invention, which will be described in detail hereinafter. It is to be understood that one or more of elements/components shown and/or described in one or more of these examples/embodiments and not in others may be used in those others too unless mechanical or other limitations prevent such an implementation. Moreover, describing features of different examples/embodiments in a single passage does not automatically mean that those features are inextricably linked. They may be applied separately from one another.

The present invention is discussed in more detail below, with reference to the attached drawings, in which:

FIG. 1a-1b illustrate top views on semiconductor-superconductor hybrid structures (1).

FIG. 1c-1e illustrate side views on semiconductor-superconductor hybrid structures (1).

FIG. 1f illustrates another top view of a semiconductor-superconductor hybrid structure (1).

FIG. 1g shows a top view on a manufacturing example of a semiconductor-superconductor hybrid structure (1).

FIG. 1h shows measurement results related to the manufacturing example of FIG. 1g.

FIG. 1i illustrates a semiconductor-superconductor hybrid structure (1) comprising one or more further quantum dots.

FIG. 2a illustrates a top view on an integrated quantum dot structure (2).

FIG. 2b illustrates a top view on an integrated quantum circuit architecture (3).

FIG. 2c illustrates a qubit subspace realizable by an integrated quantum circuit architecture (3).

FIG. 2d illustrates a further top view on an integrated quantum circuit architecture (3).

FIG. 3 illustrates quantum gates operating on an integrated quantum circuit architecture (3).

### DETAILED DESCRIPTION

The present invention brings together several technical fields such as topological superconductivity, superconducting qubits, hybrid circuit quantum electrodynamics (cQED). The inventors have realized a semiconductor-superconductor hybrid structure (1) and an integrated quantum dot structure (2) enabling high control of interactions between quantum dots, and an integrated quantum circuit architecture (3) capable of realizing protected qubits that show immunity to dielectric loss and magnetic noise and can be manipulated with a set of universal quantum gates. Examples of the structure (2) and the architecture (3) are discussed hereinbelow.

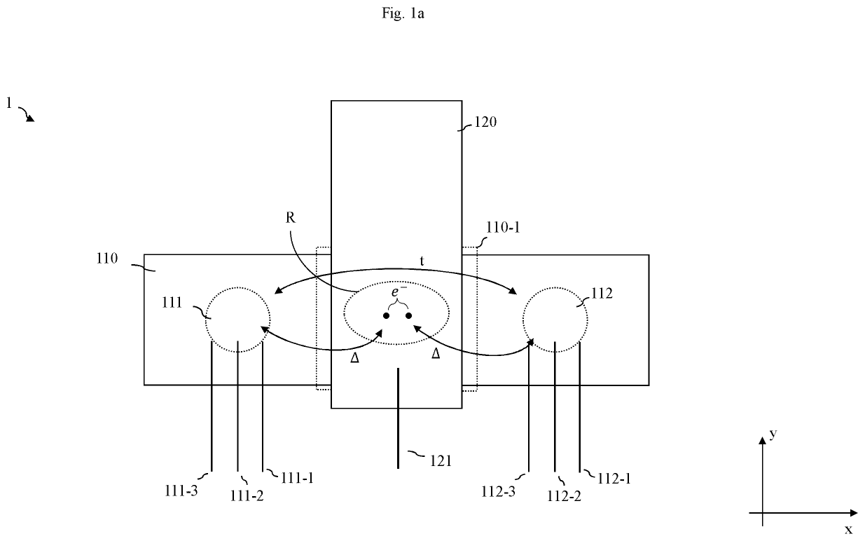

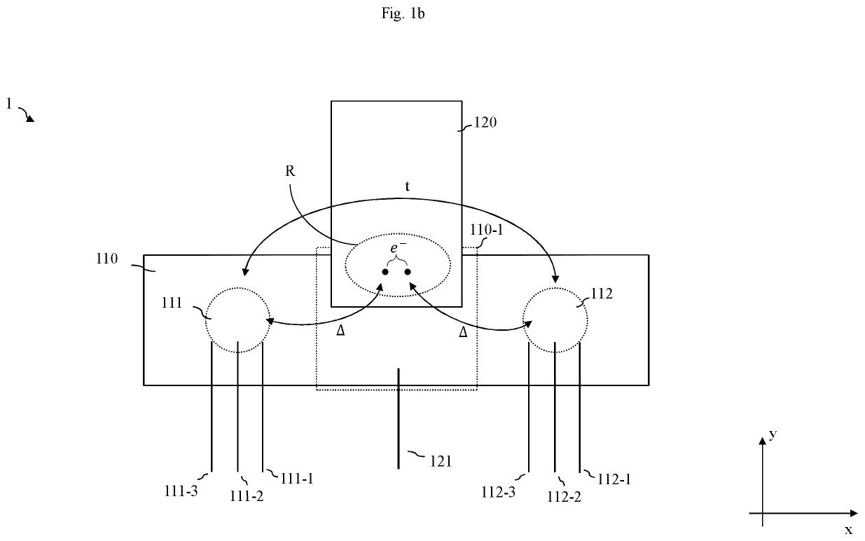

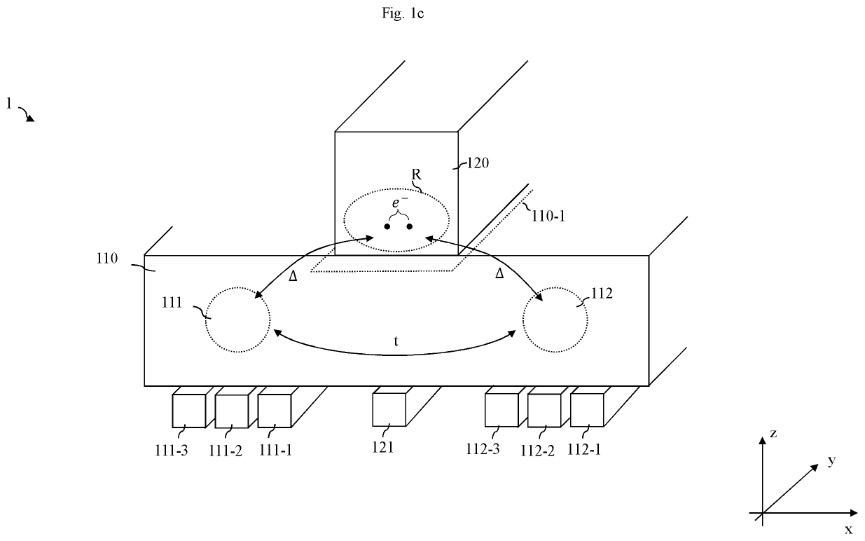

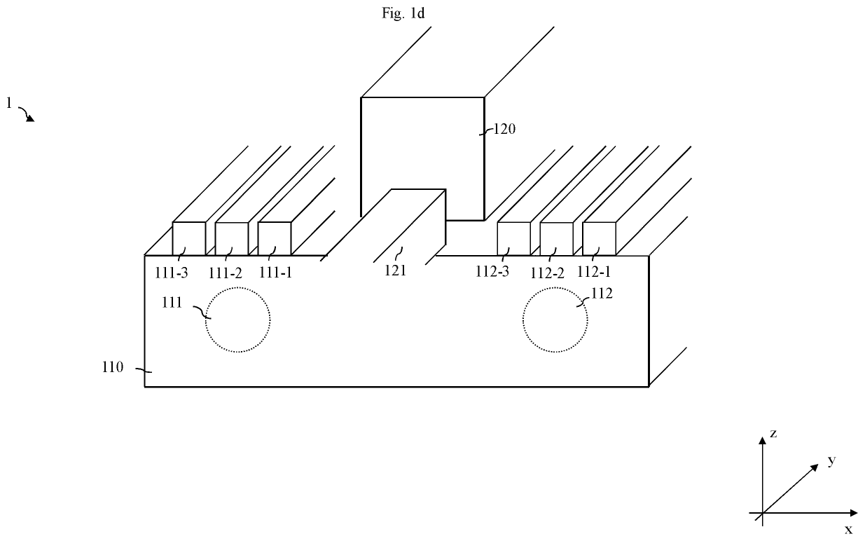

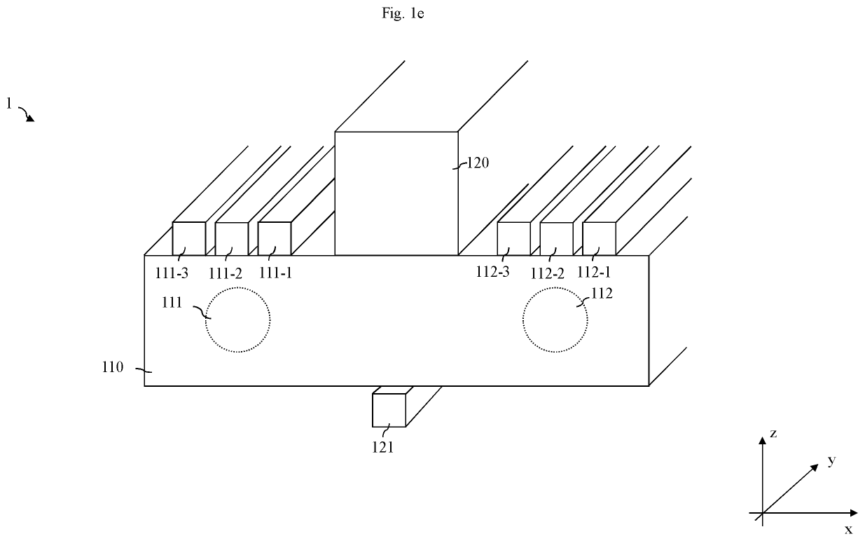

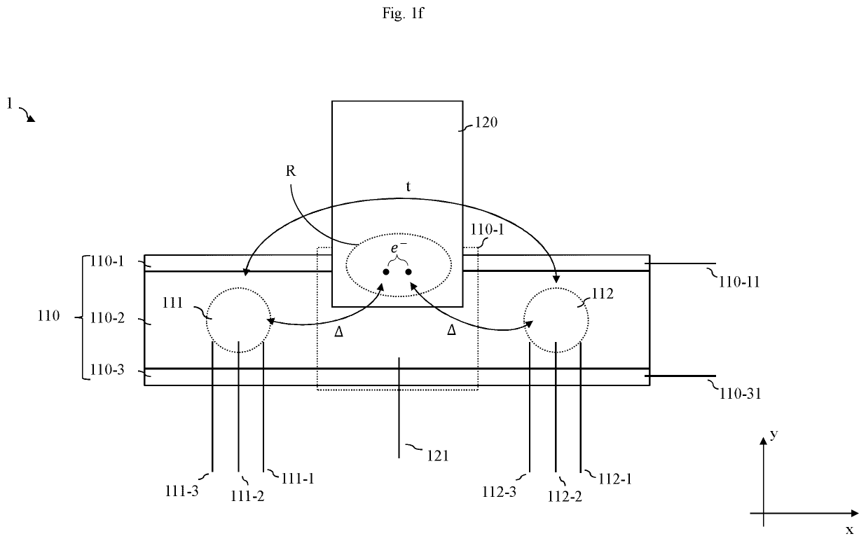

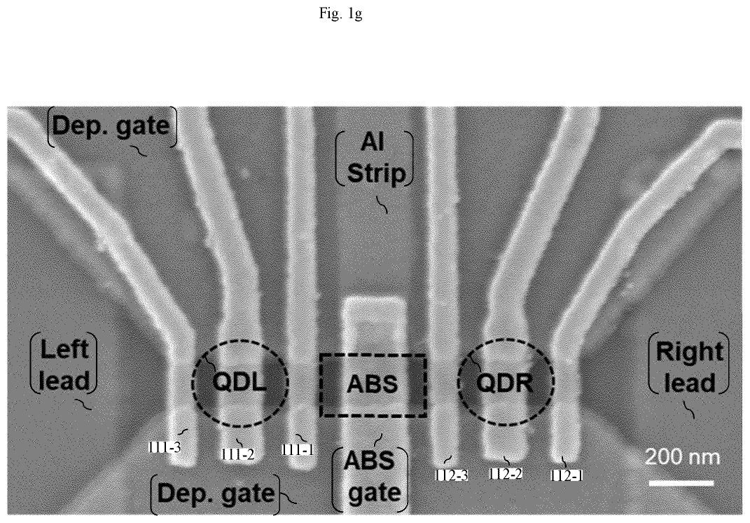

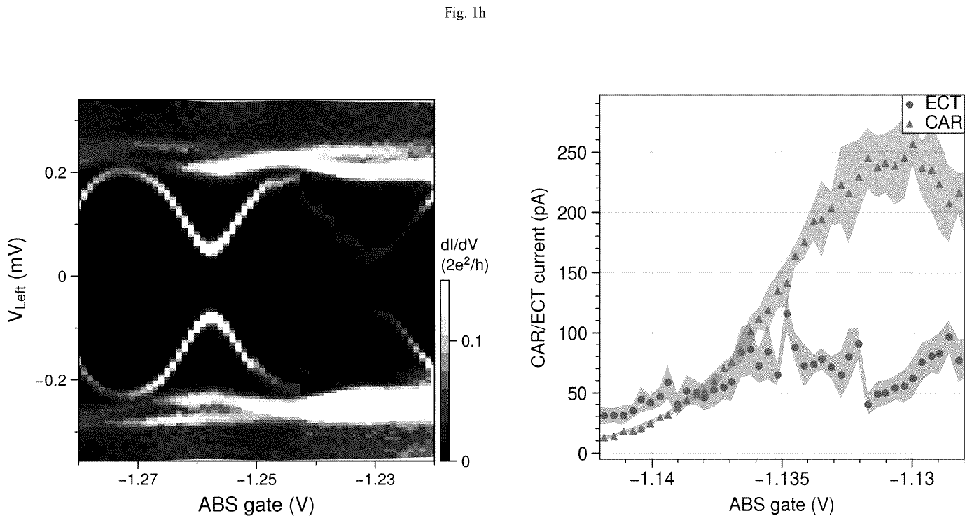

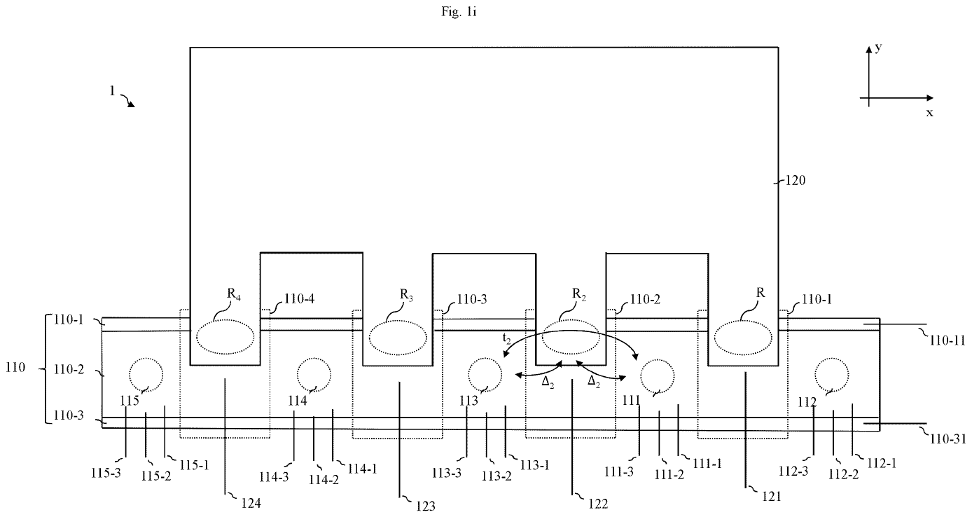

The integrated quantum dot structure (2) and the integrated quantum circuit architecture (3) build up on a semiconductor-superconductor hybrid structure (1). The semiconductor-superconductor hybrid structure (1) couples quantum dots in a specific way. Examples and aspects of such a semiconductor-superconductor hybrid structure (1) are described with reference to FIG. 1a-1i.

FIG. 1a illustrates a top view on a semiconductor-superconductor hybrid structure (1). The semiconductor-superconductor hybrid structure (1) comprises a semiconductor (110) extending in a first direction (x-axis). The semiconductor (110) hosts a first quantum dot (111) and a second quantum dot (112).

The first and second quantum dots (111, 112) may be formed in the semiconductor (110) by means of one or more electrical/electrostatic gates (111-1, 111-2, 111-3; 112-1, 112-2, 112-3). For example, the one or more electrostatic gates may be configured to provide electrostatic potentials in the semiconductor (110) so as to define confining regions that form the first and second quantum dots (111, 112). Electrostatic gates can be provided e.g. by metallic structures, e.g. lithographically defined metallic structures. As an example, an electrostatic gate (such as a lithographically defined metallic structure) may be provided below the semiconductor (110). As further examples, electrostatic gates/lithographically defined metallic structures may in addition and/or alternatively be defined next to and/or above the semiconductor (110). FIG. 1a illustrates three electrostatic gates per quantum dot, but the number of gates may depend on a chosen implementation.

The semiconductor-superconductor hybrid structure (1) further comprises a superconductor (120) extending in a second direction (y-axis) substantially perpendicular to the first direction (x-axis). The superconductor (120) is partly formed on top of the semiconductor (110) in a region (110-1) in between the first and second quantum dots (111, 112) with respect to the first direction (x-axis). In other words, a part of the superconductor (120) is formed on top of a region (110-1) of the semiconductor (110) that is located in between the first and second quantum dots (111, 112) with respect to the first direction (x-axis).

For example, as illustrated in FIG. 1a, the superconductor (120) may extend in the second direction (y-axis) so as to broadly cover the region (110-1) located in between the first and second quantum dots (111, 112) with respect to the first direction (x-axis). However, the superconductor (120) is not limited to such an arrangement. FIG. 1b for example illustrates that the superconductor (120) may extend only partly into the region (110-1). The extend to which the superconductor (120) protrudes into the region (110-1) is not limited to the shown illustrations and may for example depend on manufacturing conditions.

The semiconductor-superconductor hybrid structure (1) realizes a so-called Kitaev chain by arranging the superconductor (120) to be partly formed on the region (110-1) of the semiconductor (110), so that the first and second quantum dots (111, 112) can be coupled to each other via a coupling (t, Δ) mediated by one or more electrons (e⁻). The coupling can be controlled by control gates such as electrostatic gates and is described next.

The coupling provided by the specific arrangement of the semiconductor (110) and the superconductor (120) comprises two coupling mechanisms:
A first coupling mechanism referred to as elastic co-tunneling (ECT).
A second coupling mechanism referred to as crossed Andreev reflection (CAR).

ECT refers to single-electron tunneling with a tunnel coupling amplitude t. I.e., a single electron can transition between the first (111) and second quantum dot (112) with a probability characterized by an amplitude t, referred to as the tunnel coupling amplitude t. Higher values of the amplitude t are indicative of a higher probability of an electron transitioning from one quantum dot to the other.

CAR refers to Cooper-pair splitting with a superconducting coupling amplitude (Δ). The Cooper-pair splitting involves a pair of electrons (e) in a region (R) of the superconductor (120) that is located in proximity to the region (110-1) of the semiconductor (110), e.g. in between the first and second quantum dots (111, 112) with respect to the x-axis. The region (R) may be in an overlap of the superconductor (120) and the semiconductor (110), e.g. when viewed from the top view. By arranging the superconductor (120) to be partly formed on the region (110-1) of the semiconductor (110), a Cooper-pair can form in the region (R) involving two electrons (e) that are tunnelling back and forth between the superconductor (120) and the two quantum dots (111, 112). As the involved electrons forming the Cooper pair can spatially separate or split into the two quantum dots (111, 112), that coupling mechanism is referred to as Cooper-pair splitting. The Cooper-pair splitting occurs with an amplitude Δ, referred to as the superconducting coupling amplitude Δ. Higher values of the amplitude Δ are indicative of a higher probability of the Cooper-pair splitting in the region (R).

The semiconductor-superconductor hybrid structure (1) comprises a control gate (121) configured to control the coupling (t, Δ). For example, a control gate (121) implemented as an electrostatic gate (121), as illustrated in FIG. 1a, may be installed that is configured to tune a relative strength between the tunnel coupling amplitude t and the superconducting coupling amplitude Δ. For example, the relative strength can be controlled by changing a voltage applied on the control gate (121)/the electrostatic gate (121).

The relative strength may be tuned so as to achieve equal amplitudes t=Δ. When achieving equal amplitudes, the structure (1) can exhibit so-called Majorana bound states (MBSs) that are located in the quantum dots. In other words, by tuning the relative strength between the amplitudes t and Δ to be equal, the so-called Majorana sweet spot is achieved at which Majorana bound states emerge at the involved first and second quantum dots (111, 112). The coupling/interaction between the first and second quantum dots (111, 112) is also known to be mediated by Andreev bound states (ABSs), i.e. spatially localized quantum states that can form in a segment of the semiconductor (110) below the superconductor (120). By tuning the voltage applied on the control gate (121), one may tune an ABS energy associated with the ABSs.

More details and background regarding the couplings mechanisms ECT and CAR, their individual control via a control gate, and on realizing a semiconductor-superconductor hybrid structure (1) via nanowires can be found in may be found in [Liu et al, 2022] and [Dvir et al, 2022], which are incorporated by reference.

FIG. 1c shows a side view of the semiconductor-superconductor hybrid structure (1) in which the semiconductor (110) extends in the first direction (x-axis) and the superconductor (120) extends in the second direction (y-axis). The superconductor (120) is shown to be arranged on top of the semiconductor (110) with respect to a third direction (z-axis) to cover at least part of the region (110-1) that is located in between the first and second quantum dots (111, 112). As mentioned above, the extend to which the superconductor (120) covers the region (110-1) may vary and is not limited to the illustration. In the illustration FIG. 1c, electrostatic gates (111-1, 111-2, 111-3; 112-1, 112-2, 112-3) and the control gate (121) are arranged below and in proximity to the semiconductor (110) so as to provide confining electrostatic potentials for defining the first and second quantum dots (111, 112), respectively. However, the semiconductor-superconductor hybrid structure (1) is not limited to the illustrated arrangement. FIGS. 1d and 1e show a further arrangements of the one or more electrostatic gates (111-1, 111-2, 111-3a 112-1, 112-2, 112-3) and the control gate (121) on top of the semiconductor (110). The arrangement of the gates is not limited to the illustrations, but can be varied as needed and as preferred for example in the context of manufacturing purposes. The one or more electrostatic gates (111-1, 111-2, 111-3; 112-1, 112-2, 112-3) may be arranged so as to define and/or control the first and second quantum dots (111, 112), respectively, and the control gate (121) may be arranged so as to control the coupling (t, Δ).

Preferably, the semiconductor-superconductor hybrid structure (1) including two quantum dots (111, 112) is realized in a two-dimensional electron gas (2DEG) or a two-dimensional hole gas (2DHG). Employing a 2DEG/2DHG may be particularly suitable for providing highly controllable quantum dots involving the present specific arrangement of the superconductor (120) and the semiconductor (110).

FIG. 1f shows a top view of the semiconductor-superconductor hybrid structure (1) in which the semiconductor (110) is implemented as a two-dimensional electron gas (2DEG) and/or in a two-dimensional hole gas (2DHG). The semiconductor (110) in this example comprises a 2DEG or 2DHG (110-2) that is sandwiched with respect to the second direction (y-axis) in between depletion regions (110-1, 110-3) controlled by respective depletion gates (110-11, 110-31).

Preferably, the semiconductor (110) is based on Indium arsenide (InAs), or Indium antimonide (InSb), or Gallium arsenide (GaAs), or Germanium (Ge), or Indium arsenide antimonide (InAsSb). E.g., the semiconductor (110) may be of a III-V InAs type.

Preferably, the superconductor (120a) included is based on Aluminium (Al), or Niobium (Nb), or Niobium Titanium Nitride (NbTiN).

Preferred combinations are InAs and Al, InSb and Al, InAsSb and Al.

In summary, the structure (1) exhibits controllable dot-dot interactions between the respective involved quantum dots (111, 112).

FIG. 1g shows a manufacturing example of the structure (1) fabricated on InAsSb 2DEGs. In said manufacturing example, the superconductor (120) is implemented as an Al strip and the semiconductor (110) as an InAsSb 2DEG with respective depletion portions/gates, and a first quantum dot (QDL) and a second quantum dot (QDR) are each defined via three respective electrostatic gates (111-1, 111-2, 111-3; 112-1, 112-2, 112-3; also referred to as finger gates). A control gate, indicated as an ABS gate, is implemented as an electrostatic gate as well. A voltage applied on the ABS gate can be varied so as to control the CAR and ECT coupling strengths to a Majorana sweet spot, i.e. to being equal (t=Δ). Left and right normal leads are implemented in contact with the semiconductor (110, 2DEG) so as to enable transport of measurements on both sides. A scale bar of 200 nm indicates the scale of the implemented components of the manufacturing example. In the manufacturing example, the two depletion gates define a channel in the 2DEG, contacted on each side with the normal leads. A middle/central part of the channel is contacted by the superconducting Al strip. The quantum dots on the left (QDL) and right (QDR) are created using the respective electrostatic gates. The ABS energy corresponding to an ABS state (“ABS” ~ region 110-1) can be controlled by the (central) ABS gate.

FIG. 1h shows measurement results related to controlling the voltage applied via the ABS gate. The left graph in FIG. 1h shows that ABS energies can be tuned by the ABS gate, and the right graph shows that the CAR and ECT coupling strengths can be tuned via the ABS gate to be equal. Hence, the manufacturing example showcases highly controllable dot-dot interactions and enabling fine-tuning to the Majorana sweet spot (t=Δ).

FIG. 1i illustrates that the semiconductor (110) of the semiconductor-superconductor hybrid structure (1) preferably comprises one or more further quantum dots (113, 114, 115) so as to host an array (or: a chain) of quantum dots. When hosting further quantum dots, then between each two neighbouring quantum dots, a respective part of the superconductor (120) protrudes on a respective region (110-2, 110-3, 110-4) of the semiconductor (110), located in between the respective two neighbouring quantum dots. Each quantum dot may be defined by respective one or more gates. E.g., a further quantum dot (113) may be defined by one or more gates (113-1, 113-2, 113-3). The number of further quantum dots that the semiconductor (110) may host is not limited to the number illustrated, but the semiconductor (110) may host dozens and even hundreds of quantum dots. For example, the semiconductor (110) may host 2, 3, 4, 5, 6 quantum dots. As outlined further below, including more quantum dots may enable higher control. However, hosting more quantum dots may also increase the size of the structure (1) and thereby the effort in for example fine tuning the involved gates.

In FIG. 1i, similarly as described above with reference to FIG. 1a-b, each two neighbouring quantum dots may be coupled to each other via the specific arrangement of superconductor (120) and semiconductor (110) and the involved respective gates. The respective coupling may thus comprise both ECT and CAR type interactions/couplings, involving one or more electrons and respective regions (R₂, R₃, R₄) of the superconductor (120). The respective regions (R₂, R₃, R₄) are typically in respective overlap regions of the superconductor (120) and the semiconductor (110). Respective control gates (122, 123, 124) may be configured to control respective coupling amplitudes corresponding to ECT and CAR couplings. For illustration purposes, couplings amplitudes t₂ and Δ₂ are shown between the first quantum dot (111) and a further quantum dot (113). The corresponding control gate (122) can be configured to tune a relative strength between the coupling amplitudes, preferably to equal amplitudes t₂=Δ₂. Similarly for other further quantum dots, although not illustrated in FIG. 1i.

Each respective part of the superconductor (120) protrudes so as to enable ECT and CAR couplings between the respective pair of quantum dots. The extend to which the respective parts of the superconductor (120) protrude to cover the corresponding respective regions (110-1, 110-2, 110-3, 110-4) may vary, as mentioned above, and may depend for example on manufacturing conditions.

As illustrated in FIG. 1i, the arrangement shown therein may be implemented as well with a 2DEG/2DHG semiconductor (110a). The 2DEG/2DEG (110-2) may be formed in a region that is in between respective depletion regions (110-1, 110-3) that can be controlled by respective depletion gates (110-11, 110-31).

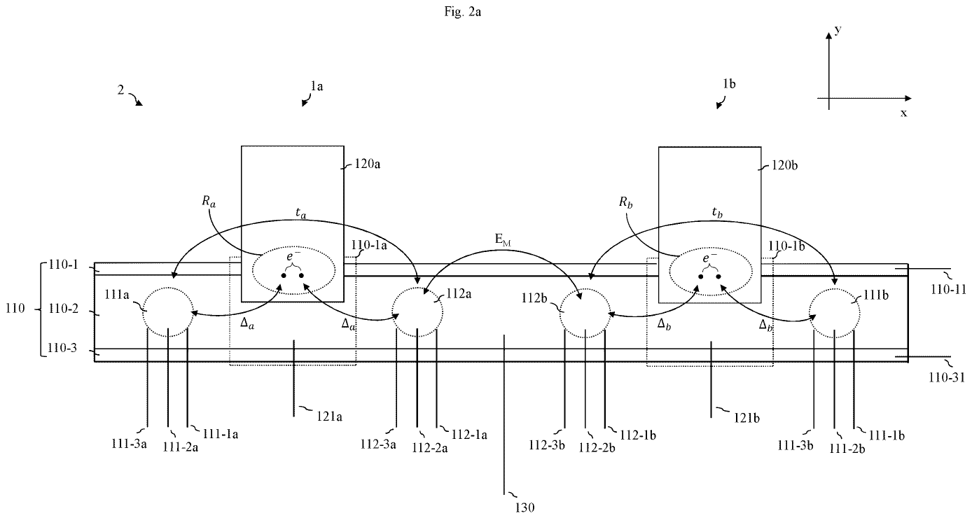

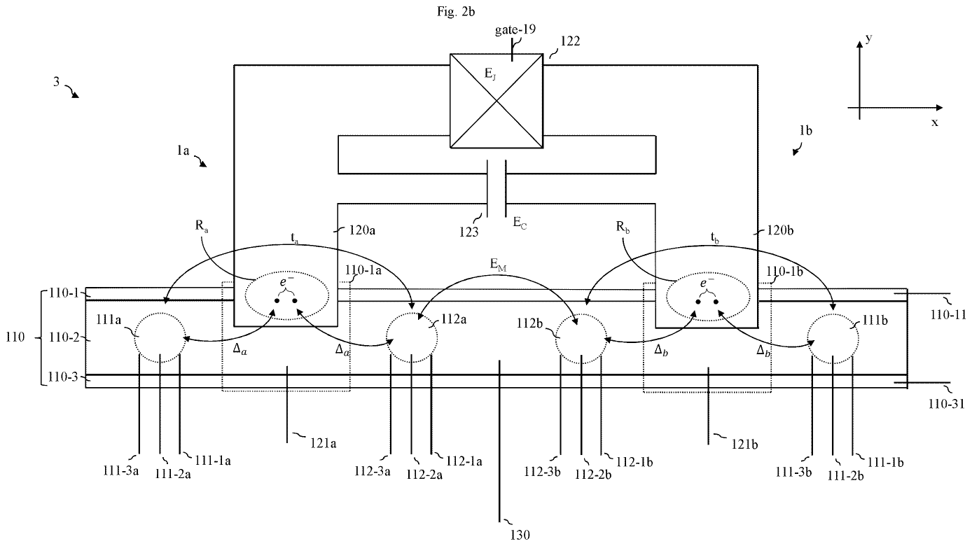

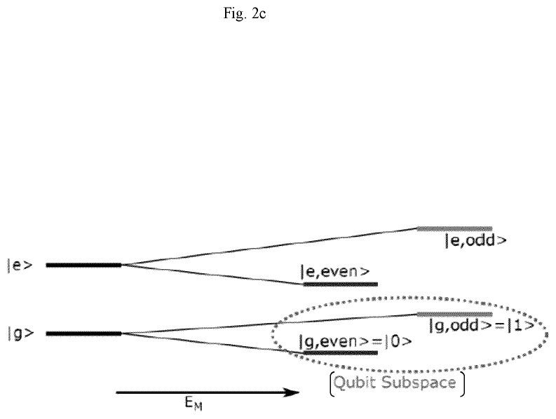

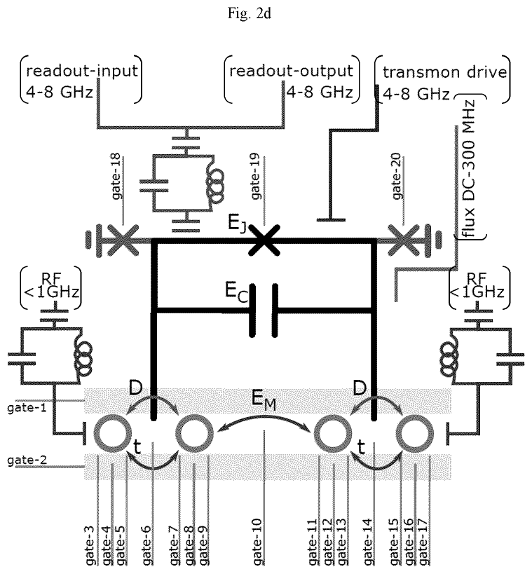

FIG. 2a illustrates a top view on an integrated quantum dot structure (2) designed by the inventors. The structure (2) provides a specific way of coupling a plurality of quantum dots and enables efficient control of interactions between quantum dots.

The integrated quantum dot structure (2) comprises a semiconductor (110) extending in a first direction (x-axis) and hosting a first quantum dot (111a), a second quantum dot (112a), a third quantum dot (112b) and a fourth quantum dot (111b).

The integrated quantum dot structure (2) further comprises a first superconductor (120a) and a second superconductor (120b), each extending in a second direction (y-axis) that is substantially perpendicular to the first direction (x-axis). The first superconductor (120a) is partly formed on top of a first region (110-1a) of the semiconductor (110) that is located in between the first and second quantum dots (111a, 112a) with respect to the first direction (x-axis). The second superconductor (120b) is partly formed on top of a second region (110-1b) of the semiconductor (110) that is located in between the third and fourth quantum dots (111b, 112b) with respect to the first direction (x-axis).

The integrated quantum dot structure (2) further comprises a first control gate (121a) configured to control a first coupling (tₐ, Δₐ) between the first and second quantum dots (111a, 112a), and a second control gate (121b) configured to control a second coupling (t_{b}, Δ_{b}) between the third and fourth quantum dots (111b, 112b). Each coupling (tₐ, Δₐ; t_{b}, Δ_{b}) is as described above with reference to the semiconductor-superconductor hybrid structure (1), i.e., is mediated by one or more electrons (e) and involves the respective superconductor (120a, 120b). Each coupling may be tuned by the respective first and second control gates (121a, 121b), e.g. to their respective Majorana sweet spot in which CAR and ECT coupling strengths are levelled.

The integrated quantum dot structure (2) further comprises an electrostatic control gate (130) configured to control a tunnel coupling amplitude (E_{M}) of single-electron tunnelling between the second quantum dot (112a) and the third quantum dot (112b).

The integrated quantum dot structure (2) may be thought of as coupling a first semiconductor-superconductor hybrid structure (la) and a second semiconductor-superconductor hybrid structure (1b) via the electrostatic control gate (130). I.e., a first chain of quantum dots (111a, 112a) that is implemented in the first semiconductor-superconductor hybrid structure (la) is coupled via the electrostatic control gate (130) to a second chain of quantum dots (112b, 111b) implemented in the second semiconductor-superconductor hybrid structure (1b), wherein a common semiconductor (110) is shared hosting the quantum dots.

The integrated quantum dot structure (2) may be substantially symmetric with respect to the electrostatic control gate (130), so as to provide the left semiconductor-superconductor hybrid structure (la) and the right semiconductor-superconductor hybrid structure (1b), respectively, which are coupled via the electrostatic control gate (130).

Each semiconductor-superconductor hybrid structure (1a, 1b) may comprise one or more or all of the components described above for a semiconductor-superconductor hybrid structure (1) with reference to FIG. 1a-1i. For example, the integrated quantum dot structure (2) may comprise, for each quantum dot (111a, 112a, 112b, 111b), respective one or more gates (111-3a, 111-2a, 111-1a, etc.) defining and/or controlling the respective quantum dot (111a, 112a, 112b, 111b). For example, the semiconductor (110) is preferably implemented as a two-dimensional electron gas (2DEG) or a two-dimensional hole gas (2DHG). The semiconductor (110) in this example comprises a 2DEG or 2DHG (110-2) that is sandwiched with respect to the second direction (y-axis) in between depletion regions (110-1, 110-3) controlled by respective depletion gates (110-11, 110-31). For example, the semiconductor (110) may comprise further quantum dots (113, 114, 115) arranged in the first direction (x-axis) and on both sides defined by the electrostatic control gate (130), so that the structure (2) couples two quantum dot chains, each quantum dot chain comprising a respective plurality of quantum dots. As illustrated in FIG. 1i and described in reference thereto, each pair of neighbouring quantum dots in a quantum dot chain may be coupled via a respective part of the respective superconductor (120a, 120b) so as to provide a respective coupling involving respective CAR and ECT coupling strengths.

The specific arrangement of the quantum dots (111a, 112a, 112b, 111b) and the first and second control gates (121a, 121b) and the electrostatic control gate (130) allows stable operation of electron transitions in between the involved quantum dots (111a, 112a, 112b, 111a). In particular, by controlling tunnel coupling amplitude (E_{M}) of single-electron tunnelling between the second quantum dot (112a) and the third quantum dot (112b) with the electrostatic gate (130), electron transitions between the two involved chains of quantum dots (111a, 112a; 112b, 111b) can be controlled efficiently after manufacturing of the integrated quantum dot structure (2). For example, manufacturing methods typically lead to structures at which distances between the components tend to vary depending on manufacturing conditions, but the specific arrangement including the electrostatic control gate (130) and the first and second control gates (121a, 121b) allows to finetune interactions between the involved quantum dots (111a, 112a; 112b, 111b), for example so as to simultaneously tune each of the first coupling (tₐ, Δₐ) between the first and second quantum dots (111a, 112a) and the second coupling (t_{b}, Δ_{b}) between the third and fourth quantum dots (111b, 112b) to their respective Majorana sweet spot (tₐ=Δₐ; t_{b}=Δ_{b}), thereby levelling CAR and ECT coupling strengths, while at the same time additionally enabling tuning of single-electron tunnelling (E_{M}) between the two chains of quantum dots (111a, 112a; 112b, 111b). The specific arrangement provided by the structure (2) allows for precise gate control of the involved MBSs and the coupling between the involved MBSs. Further advantages of the high controllability related to the specific arrangement of the structure (2) may also be recognized in the examples discussed hereinbelow in the context of the integrated quantum circuit architecture (3), which involves the structure (2).

Preferably, each of the first (tₐ, Δₐ) and second coupling (t_{b}, Δ_{b}) comprises ECT coupling related to single-electron tunnelling between the respective first and second quantum dots (111a, 112a) or third and fourth quantum dots (112b, 111b), with a respective tunnel coupling amplitude (tₐ; t_{b}).

Preferably, each of the first (tₐ, Δₐ) and second coupling (t_{b}, Δ_{b}) comprises CAR coupling related to Cooper-pair splitting with a respective superconducting coupling amplitude (Δₐ, Δ_{b}) between the respective first and second quantum dots (111a, 112a) or third and fourth quantum dots (112b, 111b), the Cooper-pair splitting involving a Cooper-pair of electrons (e) that is formed in a respective region (Ra, Rb) of the respective superconductor (120a, 120b) that is located in proximity to the respective region (110-1a, 110-1b) of the semiconductor (110).

FIG. 2b illustrates an integrated quantum circuit architecture (3) developed by the inventors, which enables the formation of a stable protected qubit whose coherence time is limited only by quasiparticle poisoning. The integrated quantum circuit architecture (3) builds up on the above discussed integrated quantum dot structure (2).

The integrated quantum circuit architecture (3) comprises an integrated quantum dot structure (2) with components as described above with reference to FIG. 1a-1i and FIG. 2a. The integrated quantum circuit architecture (3) further comprises a Josephson junction (122) and a capacitor element (123).

The Josephson junction connects the first superconductor (120a) and the second superconductor (120b), i.e. the superconductors (120a, 120b) are connected to each other so as to form the Josephson junction (122). The Josephson junction (122) is configured to exhibit a Josephson energy (E_{J}). The Josephson energy (E_{J}) may also be referred to as a Josephson coupling (E_{J}), which involves one or more Cooper pairs tunnelling across the Josephson junction (122). The integrated quantum circuit architecture (3) may comprise a control gate (gate-19) configured to tune/control the Josephson energy/coupling (E_{J}). The control gate may be implemented by e.g. one or more electrostatic gates that may be provided e.g. by a metallic structure. The Josephson coupling E can be tuned by applying a respective voltage (e.g., direct current (DC) voltage) to the electrostatic gate (e.g., to the metallic structure). For instance, a lithographically defined metallic structure may be employed to provide an electrostatic gate. As an example, an electrostatic gate (such as a lithographically defined metallic structure) may be provided below the Josephson junction (122). As further examples, electrostatic gates/lithographically defined metallic structures may in addition and/or alternatively be defined next to and/or above the Josephson junction (122) so as to provide the control gate (gate-19).

For example, as illustrated in FIG. 2b, the first superconductor (120a) may further protrude/extend into the first direction (x-axis) so as to attach to the Josephson junction (122)/to form a left part of the Josephson junction (122). Similarly, the second superconductor (120b) may further protrude/extend into the first direction (x-axis) so as to attach to the Josephson junction (122)/to form a right part of the Josephson junction (122).

The Josephson junction (122) involving the first superconductor (120a) and the second superconductor (120b) may comprise an insulating material, a normal-metal or a semiconductor. Preferably, the Josephson junction (122) involving the first and second superconductors (120a, 120b) is a Superconductor-NormalMetal-Superconductor, SNS, Josephson junction (e.g., [Casparis et al, 2018]).

The capacitor element (123) is configured to provide a capacitive coupling (E_{C}). That is, the capacitor element (123) couples the first and second superconductors (120a, 120b) via a capacitive coupling (E_{C}).

The arrangement of the architecture (3) may be such that a loop/circuit is formed by the first superconductor (120a), the Josephson junction (122), the second superconductor (120b), and the coupled chains of quantum dots (111a, 112a, 112b, 111b). I.e., the integrated quantum circuit architecture (3) can be regarded as extending the integrated quantum dot structure (2) by means of the Josephson junction (122) and the capacitor element (123) connecting the involved superconductors (120a, 120b) so as to form a quantum circuit that can exhibit a protected qubit.

FIG. 2c illustrates a qubit subspace realizable by the architecture (3). FIG. 2c showcases that when increasing the tunnel coupling amplitude E_{M} controlled by the electrostatic gate (130) (e.g., by tuning a voltage applied at the electrostatic gate (130)), a ground state (|g>) and an excited state (|e>) of the architecture (3) split into degenerate states based on parities (even, odd). The states are typically observed as low-energy states when cooling down the architecture (3) to milli-Kelvin range.

The architecture (3) enables a physical realization of a Hamiltonian known as a Majorana transmon qubit Hamiltonian (e.g., [Smith et al, 2020], Eqn (6)), which is

$$H = - {E}_{J} cos ( φ ) + 4 {E}_{c} {n}^{2} + i {γ}_{2} {γ}_{3} {E}_{M} cos ( ( φ - 2 π Φ / {Φ}_{0} ) / 2 ) ,$$

with the Josephson energy E_{J} provided by the Josephson junction (122), the capacitive coupling E_{C} provided by the capacitive element (123), the tunnel coupling amplitude E_{M} controlled by the electrostatic gate (130), an external magnetic flux Φ, Φ₀=h/2e the magnetic flux quantum (with Planck constant h and electron charge e), n may be a parameter related to an offset charge and electron numbers/Cooper-pair numbers on the first and second superconductors (120a, 120b), q a superconducting phase difference between the first and second superconductors (120a, 120b), and Majorana fermion operators γᵢ related to Majorana zero modes (MZMs). Details regarding the Hamiltonian may be found in [Smith et al, 2020] and references therein.

The architecture (3) is thus a physical realization of a quantum circuit that exhibits the above-described Hamiltonian, but in which the energy E_{M} and the energy E_{J} can be controlled separately and independently from one another. This separate controllability allows for full control of the non-linear potentials and thereby achieves the desired controllability of two quantum states forming a qubit. Such separate controllability of the energies E_{M} and E_{J} in the Hamiltonian H is a technical advantage provided by the architecture (3) relative to prior art architectures as discussed for example in [Smith et al, 2020].

As can be appreciated from the E_{M} terms, the Hamiltonian H that can be realized by the architecture (3) exhibits an energy difference that is 4π periodic in a superconducting phase difference (φ) and is therefore is distinguished from a standard transmon Hamiltonian Hₛₜ which is only 2π-periodic,

$${H}_{st} = - {E}_{J} cos ( φ ) + 4 {E}_{c} {n}^{2} + i {γ}_{2} {γ}_{3} {E}_{M} cos ( ( φ - 2 π Φ / {Φ}_{0} ) ) .$$

Therefore, the architecture (3) enables a physical realization of a protected qubit that is better protected than a standard transmon qubit (a Josephson junction shunted by a larger capacitor, [Koch et al, 2007], [Kjaergaard et al, 2020]). An example of a standard transmon architecture is the capacitively shunted superconducting quantum interference device (SQUID). The architecture (3) may be understood as a modified transmon architecture in which an effective Josephson junction is formed that exhibits a 4π-periodic energy difference.

By the specific arrangement of the components of the architecture (3) coupling a first chain of quantum dots (111a, 112a) and a second chain of quantum dots (112b, 111b), an effective Josephson junction is formed with an energy difference that is 4π periodic in a superconducting phase difference between the two involved chains of quantum dots (111a, 112a; 1126, 111b). This 4π periodic potential effectively creates a qubit subspace based on the even/odd parity between the two involved chains ([Avila et al, 2020, A], [Avila et al, 2020, B], [Smith et al, 2020]). The two chains of quantum dots (111a, 112a; 112b, 111b) (Kitaev chains) may be occupied by the same number of excitations (even parity) or a different number of excitations (odd parity). A coherence time of a qubit realized by the architecture (3) is limited only by quasiparticle poisoning and hence harnesses topological protection, as only global operations that change the global parity, which in turn can change the parity difference across the junction, can induce errors in the qubit.

Although not illustrated in FIG. 2a-2e, the semiconductor (110) may host further quantum dots (113, 114, 115) on each side of the electrostatic gate (130), respectively. Such a semiconductor (110) with further quantum dots (113,114,115) is illustrated in FIG. 1i and may be implemented in any of the structures (2) and architectures (3) as well. I.e., the semiconductor (110) may host a first chain of quantum dots and a second chain of quantum dots, wherein the first and second chains are coupled to each other via the electrostatic gate (130). In each chain, two neighbouring quantum dots may be coupled to each other as illustrated and described with reference to FIG. 1i and the figures referenced therein. Implementing larger arrays/chains of quantum dots in that way in the architecture (3) has the technical advantage of further suppressing noise. For example, a MBS energy may remain more stable as a function of detuning of Majorana sweet spots, and even more stable when further increasing the number of quantum dots in each chain.

FIG. 2d shows an example of an architecture (3) including further control elements and control gates (gate-1 to gate-20), at the example of two chains of quantum dots being coupled by an electrostatic gate (130), gate-10, via a tunnel coupling amplitude E_{M}.

As shown in FIG. 2d, a first quantum dot (111a) may be defined via electrostatic gates gate-3, gate-4, gate-5. A second quantum dot (112a) may be defined via electrostatic gates gate-7, gate-8, gate-9. A third quantum dot (112b) may be defined via electrostatic gates gate-11, gate-12, gate-13. A fourth quantum dot (111b) may be defined via electrostatic gates gate-15, gate-16, gate-17.

The second quantum dot (112a) is coupled to the third quantum dot (112b) via the electrostatic gate (130), gate-10. By tuning a voltage applied to the electrostatic gate (130), the tunnel coupling amplitude E_{M} may be controlled. Said controlled amplitude sets the energy E_{M} associated with the 4π-periodic potential of the Majorana transmon qubit Hamiltonian.

By control gates gate-6 and gate-14, respective quantum dot tunnelling (t) and superconducting tunnelling (D, corresponding to Δ in other figures) are controlled. For example, the respective amplitude (t, D) may be controlled to the respective Majorana sweet spot (t=D).

The superconductors (120a, 120b) are configured to mediate a coupling between the quantum dots (111a, 112a, 112b, 111b) and may be said to form one superconductor that is patterned to form a capacitor/capacitive element so as to provide a charging energy (E_{C}). The charging energy (E_{C}) may correspond to a small charging energy known in transmons.

A Josephson junction formed in between the superconductors (120a, 120b) exhibits a Josephson energy E_{J} and can be tuned by gate-19. Preferably, the Josephson junction is an SNS junction. The Josephson energy E_{J} controlled by the gate-19 functions as the Josephson energy in the Majorana transmon qubit Hamiltonian, i.e. the Josephson energy that is 21-periodic in the superconducting phase difference (φ), −E_{J} cos (φ).

FIG. 2d shows two additional gate-tuneable Josephson junctions to the left and right of the Josephson junction, controlled by respective gates gate-18 and gate-20. Such two additional Josephson junctions can be controlled to be fully opened so as to effectively ground either of the two islands associated with the two superconductors (120a, 120b) and can be used in a tune-up process when preparing and/or re-setting the architecture (3) in operation. Furthermore, two radio-frequency (RF) circuits indicated by “RF<1 Ghz” in FIG. 2d may be used as well in the tune-up process.

The quantum dots (111a, 112a, 112b, 111b) may be defined in a region in between two depletion gates/regions that can be controlled by gates gate-1 and gate-2.

For reading out, dispersive readout techniques well-established and developed for circuit QED platforms may be employed [Kjaergaard et al, 2020]. For the dispersive readout, a superconductor (120a, 120b) can be capacitively coupled to a readout resonator which can be probed with microwave frequencies. A readout resonator is illustrated in FIG. 2d by a circuit referenced with “readout-input 4-8 GHz” and “readout-output 4-8 GHz”.

A drive line, indicated in FIG. 2d with “transmon drive 4-8 GHz”, may be used for gate operations, i.e. for realizing quantum gates that manipulate quantum states of the architecture (3) in a controllable manner.

A flux line, indicated in FIG. 2d with “flux DC-300 MHz”, can be used to enable local flux control. For example, a magnetic flux can be controlled, the magnetic flux flowing through the loop/circuit defined by the architecture (3). For example, the loop may be a loop formed by the first superconductor (120a), the Josephson junction (122), the second superconductor (120b), and the coupled chains of quantum dots (111a, 112a, 112b, 111b).

In summary, FIG. 2d shows an example implementation of the architecture (3) in which control gates (gate-6, gate-10, gate-14, gate-19) are used so as to realize a human-built quantum circuit which at low temperatures (preferably milli-Kelvin range) exhibits a topologically protected qubit subspace (FIG. 2c). The architecture (3) thus allows for realizing the Majorana transmon qubit Hamiltonian with separate controllable energies E_{J} and E_{M}.

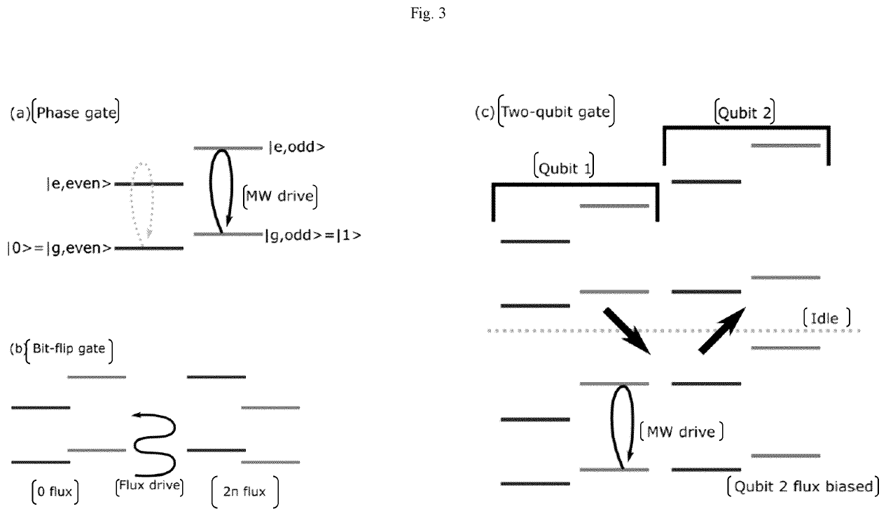

An example of controllable quantum states forming a qubit subspace and control manipulations thereof are described next with reference to FIG. 3(a) (c).

By design, a computational state |0> may be defined when a parity difference between the two coupled chains of quantum dots is even, and a further computational state |1> may be defined when the parity difference is odd. The computational states |0> and |1> define a qubit subspace. The qubit can be read out employing techniques such as described e.g. in [Avila et al, 2020, A], [Lupo et al, 2022], [Smith et al, 2020], which includes a corresponding transmon transition that enables readout and gate operations.

Next, three gates forming a universal gate set are described:
(a) A single qubit phase gate.
(b) A bit-flip gate.
(c) A two-qubit gate.

FIG. 3(a) illustrates a single qubit phase gate. One can exploit that the transmon transition is different for the qubit in the even or odd state, so that one can apply a microwave tone that is only resonant with the |g> to |e> transition (see FIG. 2c) when the qubit is in the odd state, i.e. in the computation state |1>. By driving a Rabi oscillation from |g> to |e> and back to |g>, the qubit picks up a phase π if and only if the qubit started in the |1> state. A gate can further also be engineered to yield any phase on the |1> state by slightly detuning the microwave frequency. As illustrated in FIG. 3(a), a Rabi oscillation cycle when the parity is odd is distinguished as comparted to the even parity. A transmon frequency that depends on a state of the chain of quantum dots may be understood analogously to an effect for a single quantum dot that has been observed in [Bargerbos et al, 2022].

FIG. 3(b) illustrates a bit-flip gate, which is implemented in a very different way than the phase gate since the protected nature of the qubit prohibits direct bit-flip gates. A key to create a bit-flip date is to manipulate the energy spectrum to allow for such a gate. For example, one may use the inherent flux tunability. The flux tunability arises from the specific arrangement of the components of the architecture (3): the coupled chains of quantum dots and the Josephson junction (122) form a loop through which a local magnetic flux may be applied. Since the relevant potential is 4π-periodic, as discussed further above, the energies of the |0> and |1> states are perfectly swapped at a flux equal to a single flux quantum. Just in-between, at half flux quantum, the states will therefore experience an avoided crossing and by driving a flux bias back and forth over this crossing, a bit-flip gate can be engineered. Similar gate scheme are used for example for other low-frequency superconducting qubits [Zhang et al, 2021] and can be implemented for the present architecture (3) as well. A similar periodic modulation of the charge over an energy crossing for Majorana transmons may also be found in [Lupo et al, 2022].

FIG. 3(c) illustrates a two-qubit gate that acts between two qubits (Qubit 1, Qubit 2) realized on respective architectures (3). I.e., two architectures (3) are involved and are controlled by the two-qubit gate. The two-qubit gate illustrated is a conditional phase gate, which typically corresponds to a maximally entangling two-qubit gate. The two-qubit gate involves initially preparing Qubit-2 such that its lowest transmon transition is at a larger frequency than the highest one of Qubit-1 (see FIG. 3(c)). After the initial preparing, one can apply a short flux pulse to bring these two transitions into resonance. If Qubit-1 is in the |1> state and Qubit-2 is in the |0> state, an avoided crossing will split the two transition energies. Therefore, a microwave pulse that would nominally be resonant with the transmon transition of Qubit-1 is then off-resonant and cannot be driven. As a result, nothing happens in this case. However, if Qubit-2 is in the |1> state, then Qubit-1 will pick up a phase similar as is the case in the single-qubit phase gate. As a final result, the two-qubit gate achieves that only the state |11> will pick up a phase of −1.

Preferably, a semiconductor (110) included in any one of the above-described structures/architectures is based on Indium arsenide (InAs), or Indium antimonide (InSb), or Gallium arsenide (GaAs), or Germanium (Ge), or Indium arsenide antimonide (InAsSb).

Preferably, the semiconductor (110) has a width in between 5 nm and 500 nm, more preferably in between 5 nm and 100 nm.

Preferably, a superconductor (120, 120a, 120b) included in any one of the above-described structures/architectures has a width in between 5 nm and 500 nm, more preferably in between 5 nm and 250 nm, even more preferably in between 5 nm and 100 nm.

Preferred combinations are a semiconductor (110) width in between 5 nm and 500 nm and a superconductor (120, 120a, 120b) width in between 5 and 500 nm, a semiconductor (110) width in between 5 nm and 500 nm and a superconductor (120, 120a, 120b) width in between 5 and 250 nm, a semiconductor (110) width in between 5 nm and 500 nm and a superconductor (120, 120a, 120b) width in between 5 nm and 100 nm, a semiconductor (110) width in between 5 nm and 100 nm and a superconductor (120, 120a, 120b) width in between 5 nm and 500 nm, a semiconductor (110) width in between 5 nm and 100 nm and a superconductor (120, 120a, 120b) width in between 5 nm and 250 nm, a semiconductor (110) width in between 5 nm and 100 nm and a superconductor (120, 120a, 120b) width in between 5 nm and 100 nm.

Preferably, a superconductor (120, 120a, 120b) included in any one of the above-described structures/architectures is based on Aluminium (Al), or Niobium (Nb), or Niobium Titanium Nitride (NbTiN).

Preferred combinations are InAs and Al, InSb and Al, InAsSb and Al.

Preferably, any one of the structures (1, 2) and architectures (3) is operated at a relatively low temperature of below 4 Kelvin, preferably 0-1 Kelvin. More preferably, an operating temperature in the milli-Kelvin range, e.g. 0.1-100 milli-Kelvin, is used. The structures (1, 2) and architectures (3) can be cooled down for example by a dilution refrigerator (e.g., [Krinner et al, 2019]).

### LIST OF REFERENCES

[Andersen et al, 2020] Andersen, Christian Kraglund, et al. Nature Physics 16, 875-880 (2020).
[Avila et al, 2020, A] Avila et al, Physical Review B 102, 094518 (2020).
[Avila et al, 2020, B] Avila et al, Physical Review Research 2, 033493 (2020).
[Bargerbos et al, 2022] Bargerbos, A., et al. arXiv:2208.09314 (2022).
[Casparis et al, 2018] Casparis, Lucas, et al. Nature nanotechnology 13, 915-919 (2018).
[Dvir et al, 2022] Dvir, Tom, et al. arXiv:2206.08045 (2022).
[Kjaergaard et al, 2020] Kjaergaard, Morten, et al., Annual Review of Condensed Matter Physics 11, 369-395 (2020).
[Koch et al, 2007] Koch, Jens, et al., Physical Review A 76, 042319 (2007). [Krinner et al, 2019] Krinner et al, EPJ Quantum Technology volume 6, Article number: 2 (2019).
[Liu et al, 2022] Liu, Chun-Xiao, et al. arXiv:2203.00107 (2022).
[Lupo et al, 2022] Lupo, E., E. Grosfeld, and E. Ginossar. PRX Quantum 3, 020340 (2022).
[Smith et al, 2020] Smith, Thomas B., et al., PRX Quantum 1, 020313 (2020).
[Zhang et al, 2021] Zhang, Helin, et al., Physical Review X 11, 011010 (2021)

Certain aspects are disclosed in the following clauses.

Clause 1. Semiconductor-superconductor hybrid structure (1), comprising:
a semiconductor (110) extending in a first direction (x-axis) and hosting a first quantum dot (111) and a second quantum dot (112);
a superconductor (120) extending in a second direction (y-axis) substantially perpendicular to the first direction (x-axis), the superconductor (120) being partly formed on top of a region (110-1) of the semiconductor (110) that is located in between the first and second quantum dots (111, 112) with respect to the first direction (x-axis); and
a control gate (121) configured to control a coupling (t, Δ) between the first and second quantum dots (111, 112), the coupling (t, Δ) being mediated by one or more electrons (e) and involving the superconductor (120),
wherein the semiconductor (110) is implemented as a two-dimensional electron gas, 2DEG (110-2), or a two-dimensional hole gas, 2DHG (110-2).

2. The semiconductor-superconductor hybrid structure (1) of clause 1, wherein the coupling (t, Δ) comprises:
elastic co-tunneling, ECT, related to single-electron tunneling between the first and second quantum dots (111, 112) with a tunnel coupling amplitude (t); and
crossed Andreev reflection, CAR, related to Cooper-pair splitting with a superconducting coupling amplitude (A), the Cooper-pair splitting involving a Cooper-pair of electrons (e) that is formed in a region (R) of the superconductor (120) that is located in proximity to the region (110-1) of the semiconductor (110).

3. The semiconductor-superconductor hybrid structure (1) of clause 2, wherein the control gate (121) is configured to control the coupling (t, Δ) so as to tune a relative strength between the tunnel coupling amplitude (t) and the superconducting coupling amplitude (Δ) to be equal (t=Δ).

4. The semiconductor-superconductor hybrid structure (1) of any one of clauses 1-3, wherein the semiconductor (110) further comprises one or more further quantum dots (113, 114, 115) so as to host a chain of quantum dots (113, 114, 115, 112, 111), wherein in between each two neighbouring quantum dots, a respective part of the superconductor (120) protrudes on a respective region (110-2, 110-3, 110-4) of the semiconductor (110), the respective region (110-2, 110-3, 110-4) being located in between the respective two neighbouring quantum dots.

5. Integrated quantum dot structure (2), comprising:
a semiconductor (110) extending in a first direction (x-axis) and hosting a first quantum dot (111a), a second quantum dot (112a), a third quantum dot (112b) and a fourth quantum dot (111b);
a first superconductor (120a) extending in a second direction (y-axis) substantially perpendicular to the first direction (x-axis), the first superconductor (120a) being partly formed on top of a first region (110-1a) of the semiconductor (110), the first region (110-1a) being located in between the first and second quantum dots (111a, 112a) with respect to the first direction (x-axis);
a first control gate (121a) configured to control a first coupling (tₐ, Δₐ) between the first and second quantum dots (111a, 112a), the first coupling (tₐ, Δₐ) being mediated by one or more electrons (e) and involving the first superconductor (120a);
a second superconductor (120b) extending in the second direction (y-axis), the second superconductor (120b) being partly formed on top of a second region (110-1b) of the semiconductor (110), the second region (110-1b) being located in between the third and fourth quantum dots (112b, 111b) with respect to the first direction (x-axis);
a second control gate (121b) configured to control a second coupling (t_{b}, Δ_{b}) between the third and fourth quantum dots (112b, 111b), the second coupling (t_{b}, Δ_{b}) being mediated by one or more electrons (e) and involving the second superconductor (120b); and an electrostatic control gate (130) configured to control a tunnel coupling amplitude (E_{M}) of single-electron tunnelling between the second quantum dot (112a) and the third quantum dot (112b).

6. The integrated quantum dot structure (2) of clause 5,
wherein each of the first (tₐ, Δₐ) and second coupling (t_{b}, Δ_{b}) comprises elastic co-tunnelling, ECT, coupling related to single-electron tunnelling between the respective first and second quantum dots (111a, 112a) or third and fourth quantum dots (112b, 111b), with a respective tunnel coupling amplitude (tₐ; t_{b}), and
wherein each of the first (tₐ, Δₐ) and second coupling (t_{b}, Δ_{b}) comprises crossed Andreev reflection, CAR, coupling related to Cooper-pair splitting with a respective superconducting coupling amplitude (Δₐ, Δ_{b}) between the respective first and second quantum dots (111a, 112a) or third and fourth quantum dots (112b, 111b), the Cooper-pair splitting involving a Cooper-pair of electrons (e) that is formed in a respective region (Ra, Rb) of the respective superconductor (120a, 120b) that is located in proximity to the respective region (110-1a, 110-1b) of the semiconductor (110).

7. Integrated quantum circuit architecture (3), comprising:
an integrated quantum dot structure (2) according to any one of clauses 5-6;
a Josephson junction (122); and
a capacitor element (123);
wherein the first superconductor (120a) and the second superconductor (120b) are connected to each other so as to form the Josephson junction (122),
wherein the Josephson junction (122) is configured to exhibit a Josephson energy (E_{J}),
wherein the capacitor element (123) is configured to provide a capacitive coupling (E_{C}),
wherein a loop is formed by the first superconductor (120a), the Josephson junction (122), the second superconductor (120b), and the quantum dots (111a, 112a, 112b, 111b).

8. The integrated quantum circuit architecture (3) of clause 7, wherein the Josephson junction (122) involving the first and second superconductors (120a, 120b) forms a Superconductor-NormalMetal-Superconductor, SNS, Josephson junction.

9. The integrated quantum circuit architecture (3) of any one of clauses 7-8,
wherein the first control gate (121a) is further configured to tune a relative strength between the first tunnel coupling amplitude (tₐ) and the first superconducting coupling amplitude (Δₐ) to be equal (tₐ=Δₐ); and
wherein the second control gate (121b) is further configured to tune a relative strength between the second tunnel coupling amplitude (t_{b}) and the second superconducting coupling amplitude (Δ_{b}) to be equal (t_{b}=Δ_{b}).

10. The integrated quantum circuit architecture (3) of clause 7, further comprising a control gate (gate 19) configured to control the Josephson energy (E_{J}) of the Josephson junction (122).

11. The integrated quantum dot structure (2) or the integrated quantum circuit architecture (3) of any one of the preceding clauses, wherein the semiconductor (110) is implemented as a two-dimensional electron gas, 2DEG (110-2), or a two-dimensional hole gas, 2DHG (110-2).

12. The semiconductor-superconductor hybrid structure (1), the integrated quantum dot structure (2) or the integrated quantum circuit architecture (3) of any one of the preceding clauses, wherein the superconductor (120a, 120b, 120) has a width in between 5 nm and 250 nm.

13. The semiconductor-superconductor hybrid structure (1), the integrated quantum dot structure (2) or the integrated quantum circuit architecture (3) of any one of the preceding clauses, wherein the semiconductor (110) has a width in between 5 nm and 500 nm.

14. The semiconductor-superconductor hybrid structure (1), the integrated quantum dot structure (2) or the integrated quantum circuit architecture (3) of any one of the preceding clauses,
wherein the semiconductor (110) is based on one or more of Indium arsenide, InAs, or Indium antimonide, InSb, or Gallium arsenide, GaAs, or Germanium, Ge, or Indium arsenide antimonide, InAsSb,
wherein the superconductor (120, 120a, 120b) is based on one or more of Aluminium, Al, or Niobium, Nb, or Niobium Titanium Nitride, NbTiN.

15. The semiconductor-superconductor hybrid structure (1), the integrated quantum dot structure (2) or the integrated quantum circuit architecture (3) of any one of the preceding clauses,
wherein the semiconductor (110) is based on Indium arsenide, InAs, and the superconductor (120, 120a, 120b) is based on Aluminium, Al, or
wherein the semiconductor (110) is based on Indium antimonide, InSb, and the superconductor (120, 120a, 120b) is based on Al, or
wherein the semiconductor (110) is based on Indium arsenide antimonide, InAsSb, and the superconductor (120, 120a, 120b) is based on Al.

1. Integrated quantum circuit architecture comprising an integrated quantum dot structure that comprises:
a semiconductor extending in a first direction and hosting a first quantum dot, a second quantum dot, a third quantum dot and a fourth quantum dot;
a first superconductor extending in a second direction substantially perpendicular to the first direction, the first superconductor being partly formed on top of a first region of the semiconductor, the first region being located in between the first and second quantum dots with respect to the first direction;
a first control gate configured to control a first coupling between the first and second quantum dots, the first coupling being mediated by one or more electrons and involving the first superconductor;
a second superconductor extending in the second direction, the second superconductor being partly formed on top of a second region of the semiconductor, the second region being located in between the third and fourth quantum dots with respect to the first direction;
a second control gate configured to control a second coupling between the third and fourth quantum dots, the second coupling being mediated by one or more electrons and involving the second superconductor; and
an electrostatic control gate configured to control a tunnel coupling amplitude of single-electron tunnelling between the second quantum dot and the third quantum dot;
wherein the integrated quantum circuit architecture further comprises:
a Josephson junction; and
a capacitor element;
wherein the first superconductor and the second superconductor are connected to each other so as to form the Josephson junction,
wherein the Josephson junction is configured to exhibit a Josephson energy,
wherein the capacitor element is configured to provide a capacitive coupling,
wherein a loop is formed by the first superconductor, the Josephson junction, the second superconductor, and the quantum dots.

2. The integrated quantum circuit architecture of claim 1,
wherein each of the first and second coupling comprises elastic co-tunnelling, ECT, coupling related to single-electron tunnelling between the respective first and second quantum dots or third and fourth quantum dots, with a respective tunnel coupling amplitude (tₐ; t_{b}), and
wherein each of the first and second coupling comprises crossed Andreev reflection, CAR, coupling related to Cooper-pair splitting with a respective superconducting coupling amplitude between the respective first and second quantum dots or third and fourth quantum dots, the Cooper-pair splitting involving a Cooper-pair of electrons that is formed in a respective region of the respective superconductor that is located in proximity to the respective region of the semiconductor.

3. The integrated quantum circuit architecture of claim 1,
wherein the Josephson junction involving the first and second superconductors forms a Superconductor-NormalMetal-Superconductor, SNS, Josephson junction.

4. The integrated quantum circuit architecture of claim 1,
wherein the first control gate is further configured to tune a relative strength between the first tunnel coupling amplitude and the first superconducting coupling amplitude to be equal; and
wherein the second control gate is further configured to tune a relative strength between the second tunnel coupling amplitude and the second superconducting coupling amplitude to be equal.

5. The integrated quantum circuit architecture of claim 1, further comprising a control gate configured to control the Josephson energy of the Josephson junction.

6. The integrated quantum circuit architecture of claim 1, wherein the semiconductor is implemented as a two-dimensional electron gas, 2DEG, or a two-dimensional hole gas, 2DHG.

7. The integrated quantum circuit architecture of claim 1, wherein the superconductor has a width in between 5 nm and 250 nm.

8. The integrated quantum circuit architecture of claim 1, wherein the semiconductor has a width in between 5 nm and 500 nm.

9. The integrated quantum circuit architecture of claim 1,
wherein the semiconductor is based on one or more of Indium arsenide, InAs, or Indium antimonide, InSb, or Gallium arsenide, GaAs, or Germanium, Ge, or Indium arsenide antimonide, InAsSb,
wherein the superconductor is based on one or more of Aluminium, Al, or Niobium, Nb, or Niobium Titanium Nitride, NbTiN.

10. The integrated quantum circuit architecture of claim 1,
wherein the semiconductor is based on Indium arsenide, InAs, and the superconductor is based on Aluminium, Al, or
wherein the semiconductor is based on Indium antimonide, InSb, and the superconductor is based on Al, or
wherein the semiconductor is based on Indium arsenide antimonide, InAsSb, and the superconductor is based on Al.
